(19) United States
(12) Patent Application Publication
(10) Pub. No.: US 2026/0018504 A1
(43) Pub. Date: Jan. 15, 2026

(54) REDISTRIBUTION STRUCTURE AND SEMICONDUCTOR PACKAGE INCLUDING THE SAME

(71) Applicant: Samsung Electronics Co., Ltd., Suwon-si (KR)

(72) Inventors: Taehoon LEE, Suwon-si (KR); Sunguk LEE, Suwon-si (KR); Gyujin CHOI, Suwon-si (KR); Younjeong CHOE, Suwon-si (KR)

(73) Assignee: Samsung Electronics Co., Ltd., Suwon-si (KR)

(21) Appl. No.: 19/022,420

(22) Filed: Jan. 15, 2025

(30) Foreign Application Priority Data
Jul. 11, 2024 (KR) 10-2024-0091871

(51) Int. Cl. H01L 23/498; H01L 21/48; H01L 23/00; H01L 23/31; H01L 23/522; H01L 23/538; H01L 25/10

(52) U.S. Cl. CPC H01L 23/49822; H01L 23/49833; H01L 23/49838; H01L 23/49894; H01L 23/5385; H01L 21/4857; H01L 23/3128; H01L 23/5222; H01L 24/05; H01L 24/08; H01L 24/13; H01L 24/16; H01L 24/96; H01L 24/97; H01L 25/105; H01L 2224/05611; H01L 2224/05616; H01L 2224/05624; H01L 2224/05639; H01L 2224/05644; H01L 2224/05647; H01L 2224/05655; H01L 2224/05666; H01L 2224/08225; H01L 2224/13111; H01L 2224/13116; H01L 2224/13124; H01L 2224/13139; H01L 2224/13144; H01L 2224/13147; H01L 2224/13155; H01L 2224/13166; H01L 2224/16227; H01L 2224/96; H01L 2224/97; H01L 2225/1023; H01L 2225/1035; H01L 2924/1815

(57) ABSTRACT

Provided is a redistribution structure having reduced parasitic capacitance. The redistribution structure may include a via layer and a wiring layer disposed on the via layer in a first direction perpendicular to the via layer, the wiring layer including a metal plate and a first insulation pattern configured to penetrate the metal plate in the first direction. An outer side surface of the first insulation pattern may be exposed from a side surface of the metal plate.

### CROSS-REFERENCE TO RELATED APPLICATION(S)

This application claims the benefit of Korean Patent Application No. 10-2024-0091871, filed on Jul. 11, 2024, in the Korean Intellectual Property Office, the disclosure of which is incorporated herein by reference.

### BACKGROUND

### 1. Field of the Invention

At least some example embodiments relate to a redistribution structure and/or to a semiconductor package including the same.

### 2. Description of the Related Art

With development of electronic industry, demand for higher functionalization, higher speed, and miniaturization of electronic components is increasing. To address such a trend, a method of, for example, stacking and mounting multiple semiconductor chips on one package wiring structure or a method of stacking a package on another package may be used. For example, a package-in-package (PIP)-type semiconductor package or a package-on-package (POP)-type semiconductor package may be used.

Meanwhile, ways to reduce and address parasitic capacitance occurring in wiring as the semiconductor package is miniaturized and highly integrated are desired.

### SUMMARY

Some inventive concepts relate to, for example, a redistribution structure having reduced parasitic capacitance in wiring(s) and/or to a semiconductor package including the same.

Some inventive concepts relate to, for example, a redistribution structure having improved electrical reliability and/or to a semiconductor package including the same.

However, the goals to be achieved by example embodiments of the present inventive concepts are not limited to the objectives described above and other objects may be clearly understood from the following example embodiments by those skilled in the art.

According to some example embodiments, a redistribution structure may include a via layer and a wiring layer on the via layer in a first direction perpendicular to the via layer, wherein the wiring layer includes a metal plate and a first insulation pattern configured to penetrate the metal plate in the first direction, and wherein an outer side surface of the first insulation pattern is exposed from a side surface of the metal plate.

According to some example embodiments, a semiconductor package may include a package substrate including a first redistribution structure and a semiconductor chip on the package substrate and electrically connected to the first redistribution structure, wherein the first redistribution structure includes a first via layer and a first wiring layer on the first via layer in a first direction perpendicular to the first via layer, the first wiring layer including a metal plate and a first insulation pattern configured to penetrate the metal plate in the first direction, and wherein an outer side surface of the first insulation pattern and a side surface of the metal plate are coplanar with each other.

According to some example embodiments, a redistribution structure may include a via layer including an insulation film and a via pattern penetrating the insulation film, and a wiring layer including a metal plate and a first insulation pattern, the metal player being on the via layer, the first insulation pattern penetrating the metal plate, wherein the first insulation pattern includes a first penetration part and a second penetration part, and a connection part, the first penetration part and the second penetration part penetrating the metal plate, the connection part connecting the first penetration part to the second penetration part, a first side surface of the wiring layer includes an outer side surface of the first insulation pattern and a first side surface of the metal plate that are coplanar with each other, and a second side surface of the wiring layer includes only the metal plate except for the first insulation pattern.

Additional aspects of some example embodiments will be set forth in part in the description which follows and, in part, will be apparent from the description, or may be learned by practice of inventive concepts.

According to example embodiments, it is possible to reduce parasitic capacitance in wiring of a semiconductor package.

According to example embodiments, it is possible to improve electrical reliability of a semiconductor package.

### BRIEF DESCRIPTION OF THE DRAWINGS

These and/or other aspects, features, and advantages of inventive concepts will become apparent and more readily appreciated by one of ordinary skill in the art from the following description of some example embodiments, taken in conjunction with the accompanying drawings of which:

FIG. 1 is a diagram illustrating a redistribution structure according to some example embodiments;

FIG. 2 is a diagram illustrating a first side surface of a redistribution structure according to some example embodiments;

FIG. 3 is a diagram illustrating a second side surface of a redistribution structure according to some example embodiments;

FIG. 4 is a diagram illustrating a first insulation pattern of a redistribution structure according to some example embodiments;

FIG. 5 is a diagram illustrating a cross section taken along line A-A′ of FIG. 1;

FIGS. 6 through 10 are diagrams illustrating a redistribution structure according to some other example embodiments;

FIG. 11 is a diagram illustrating a semiconductor package according to some example embodiments;

FIG. 12 is a diagram illustrating a semiconductor package according to some example embodiments; and

FIGS. 13 through 20 are diagrams illustrating an intermediate operation relating toa method of manufacturing a semiconductor package according to some example embodiments.

### DETAILED DESCRIPTION

Before example embodiments are described, terms or words used in the present description and the accompanying claims are not to be limited to general definitions or dictionary definitions. The terms and words are to be construed under a principle that an inventor may appropriately define a concept of a term in order to describe their invention in the best way. Accordingly, since example embodiments according to inventive concepts and configurations illustrated in the accompanying drawings are merely some desirable example embodiments and do not represent all of the technical spirit and scope of the inventive concepts, it should be understood that various equivalents and modifications that may replace the example embodiments and configurations may be present at the time of filing the application of the present disclosure.

In the following descriptions, terms in a singular form include terms a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description.

Hereinafter, some example embodiments of inventive concepts will be described with reference to the drawings.

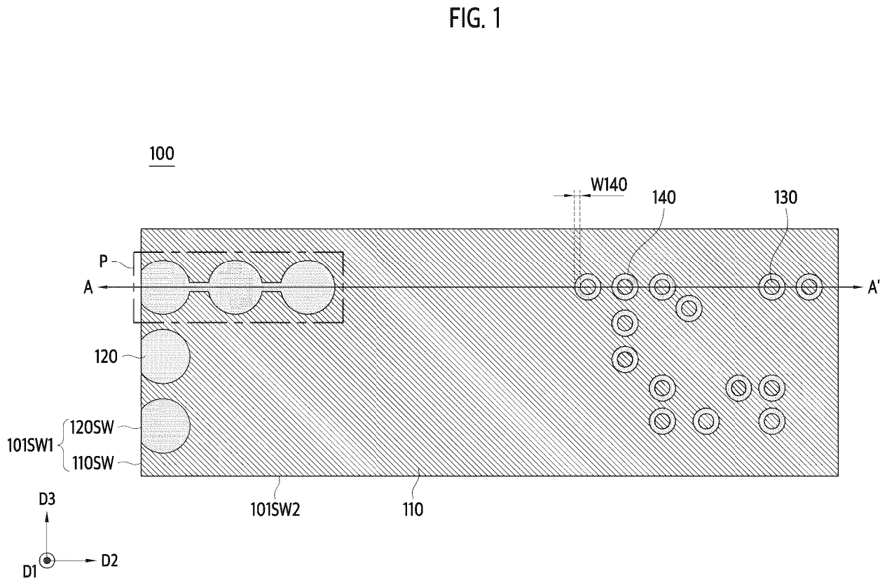

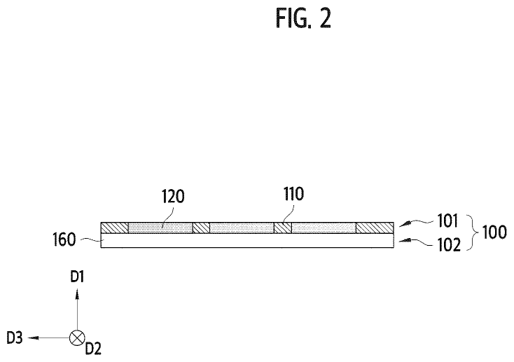

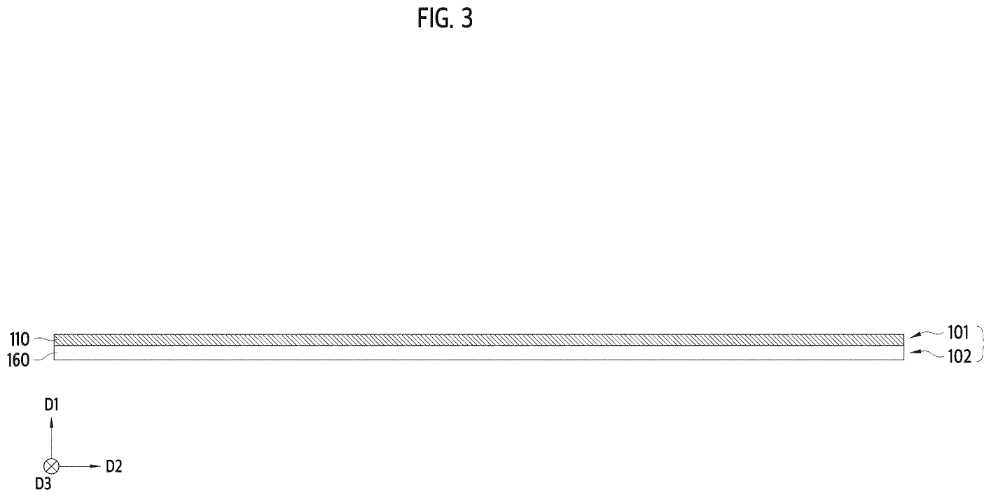

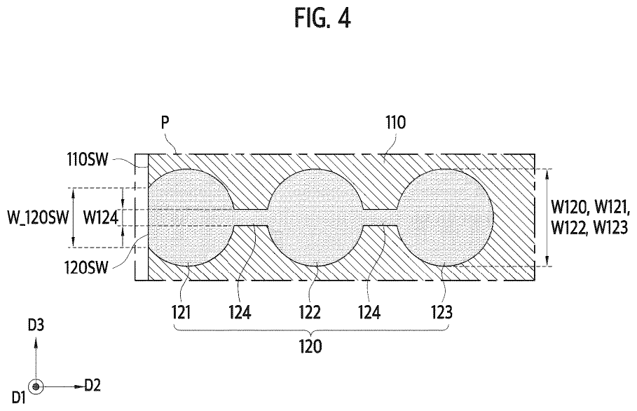

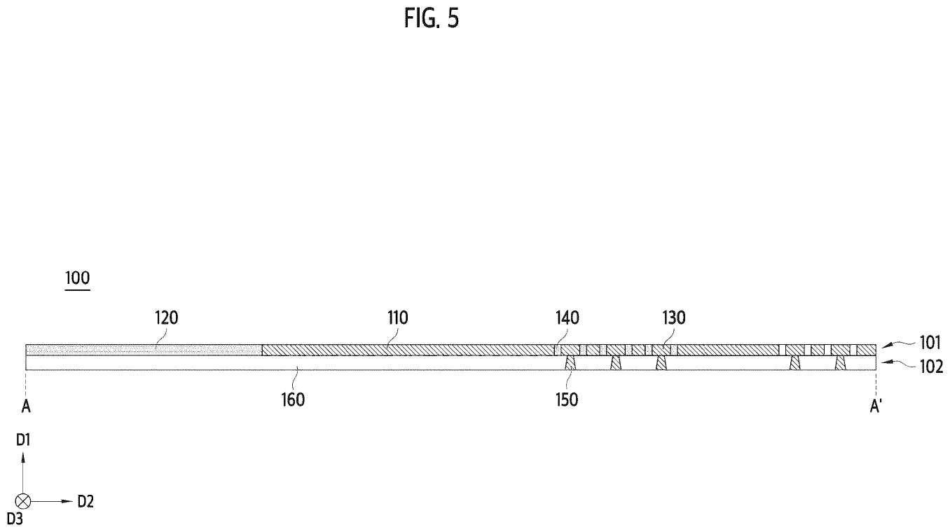

FIG. 1 is a diagram illustrating a redistribution structure according to some example embodiments. FIG. 2 is a diagram illustrating a first side surface of a redistribution structure according to some example embodiments. FIG. 3 is a diagram illustrating a second side surface of a redistribution structure according to some example embodiments. FIG. 4 is a diagram illustrating a first insulation pattern of a redistribution structure according to some example embodiments. FIG. 5 is a diagram illustrating a cross section taken along line A-A′ of FIG. 1.

Referring to FIGS. 1 through 5, a redistribution structure 100 according to some example embodiments may include a wiring layer 101 and a via layer 102.

According to some example embodiments, the wiring layer 101 may be disposed on the via layer 102. The wiring layer 101 may be stacked on the via layer 102 in a first direction D1. At this point, the first direction D1 may be a direction perpendicular to the via layer 102. The first direction D1 may be a direction crossing a second direction and a third direction that are parallel to a metal plate 110. The wiring layer 101 may include the metal plate 110, a first insulation pattern 120, a wiring pattern 130, and a second insulation pattern 140.

According to some example embodiments, the metal plate 110 may be disposed on the via layer 102. The metal plate 110 may cover or at least partially cover the via layer 102. The metal plate 110 may include a conductive material. For example, the metal plate 110 may include copper (Cu), aluminum (Al), silver (Ag), tin (Sn), gold (Au), nickel (Ni), lead (Pb), titanium (Ti), and/or any alloy thereof, but example embodiments are not limited thereto.

According to some example embodiments, the first insulation pattern 120 may penetrate (for example, extend or at least partially extend through) the metal plate 110 in the first direction D1. The first insulation pattern 120 may be surrounded or at least partially surrounded by the metal plate 110. The first insulation pattern 120 may include an insulation material. For example, the first insulation pattern 120 may include an oxide film, a nitride film, a carbide film, a polymer, or a combination thereof, but example embodiments are not limited thereto. According to some example embodiments, the first insulation pattern 120 may include a photoimageable dielectric material, but example embodiments are not limited thereto. For example, the first insulation pattern 120 may include a photoimageable dielectric (PID) and/or photosensitive polyimide (PSPI).

According to some example embodiments, the first insulation pattern 120 may include a first penetration part 121, a second penetration part 122, a third penetration part 123, and a connection part 124.

According to some example embodiments, the first penetration part 121, the second penetration part 122, and the third penetration part 123 may penetrate the metal plate 110 in the first direction D1. In the first direction D1, a thickness of the first penetration part 121, a thickness of the second penetration part 122, and a thickness of the third penetration part 123 may be equal. However, example embodiments are not limited thereto. For example, in the first direction D1, the thickness of the first penetration part 121, the thickness of the second penetration part 122, and the thickness of the third penetration part 123 may be different.

According to some example embodiments, the first penetration part 121, the second penetration part 122, and the third penetration part 123 may have a circular shape when viewed in the first direction D1. However, example embodiments are not limited thereto. For example, the first penetration part 121, the second penetration part 122, and the third penetration part 123 may have various shapes such as a quadrangular shape, a hexagonal shape, or the like.

According to some example embodiments, the first penetration part 121 may be a penetration part disposed to be most adjacent (for example, proximate) to a side surface 110SW of the metal plate among penetration parts 121, 122, 133. The first penetration part 121 may have an area viewed in the first direction D1 smaller than those of the second penetration part 122 and the third penetration part 123. For example, when viewed in the first direction D1, the second penetration part 122 and the third penetration part 123 may have a full circular shape, and the first penetration part 121 may have a circular shape of which at least a portion is cut, but example embodiments are not limited thereto. A side surface 120SW of the first insulation pattern may not be covered by the metal plate 110 and may be a side surface of the first penetration part 121, which is exposed from the side surface 110SW of the metal plate.

According to some example embodiments, when viewed in the first direction D1 which is perpendicular to a surface of the metal plate 110, an area of each of the first penetration part 121, the second penetration part 122, and the third penetration part 123 may be larger than an area of the wiring pattern 130. For example, in a third direction D3, a width W121 of the first penetration part, a width W122 of the second penetration part, and a width W123 of the third penetration part may be larger than a diameter of the wiring pattern 130 which has a circular shape.

According to some example embodiments, when viewed in the first direction D1 which is perpendicular to the surface of the metal plate 110, areas of the first penetration part 121, the second penetration part 122, and the third penetration part 123 may be larger than an area of the second insulation pattern 140. A maximum width of each of the penetration parts 121, 122, and 123 may be larger than a maximum width of the second insulation pattern 140. For example, a maximum width of the first penetration part 121 may be larger than the maximum width of the second insulation pattern 140. At this point, a maximum diametric distance of the first penetration part 121 may be referred to as the maximum width of the first penetration part 121 when the first penetration part 121 have the circular shape. Also, a shortest distance from an outer circumference of the insulation pattern 130 to an outer circumference of the second insulation pattern 140 may be referenced to as the maximum width of the second insulation pattern 140.

According to some example embodiments, the maximum width of the first penetration part 121 may be, for example, a diametric distance W121 of the first penetration part 121 in the third direction D3. Also, a maximum width W140 of the second insulation pattern 140 may be the shortest distance from the outer circumference of the insulation pattern 130 which is surrounded or at least partially surrounded by the second insulation pattern 140 to the outer circumference of the second insulation pattern 140. Similarly, a maximum width of the second penetration part 122 may be a diametric distance W122 of the second penetration part 122 in the third direction D3, which may be larger than the maximum width W140 of the second insulation pattern 140.

According to some example embodiments, the connection part 124 may connect the first penetration part 121, the second penetration part 122, and the third penetration part 123. For example, the connection part 124 may be disposed between the first penetration part 121 and the second penetration part 122 to connect the first penetration part 121 and the second penetration part 122.

According to some example embodiments, the connection part 124 may be extended in a second direction D2 in which the first penetration part 121, the second penetration part 122, and the third penetration part 123 are disposed. In the third direction D3 which crosses the first direction D1 and the second direction D2, a width W124 of the connection part may be smaller than widths of the penetration parts 121, 122, and 123. The third direction D3 may be parallel to the surface of the metal plate 110. For example, in the third direction D3, the width W124 of the connection part may be smaller than a width W121 of the first penetration part and a width W122 of the second penetration part, but example embodiments are not limited thereto.

According to some example embodiments, the first insulation pattern 120 may be disposed on an insulation film 160 on the via layer 102. A lower surface of the first insulation pattern 120 may be in contact with an upper surface of the insulation film 160. The first insulation pattern 120 may overlap or at least partially overlap with the insulation film 160 in the first direction D1.

According to some example embodiments, the wiring pattern 130 may be disposed on a via pattern 150 of the via layer 102. The wiring pattern 130 may overlap or at least partially overlap with the via pattern 150 in the first direction D1. The wiring pattern 130 may be electrically connected with the via pattern 150. The wiring pattern 130 and the via pattern 150 electrically connected with each other may be used in electrical signal transmission.

According to some example embodiments, the wiring pattern 130 may include a material identical to that of the metal plate 110. For example, the wiring pattern 130 may include copper (Cu), aluminum (Al), silver (Ag), tin (Sn), gold (Au), nickel (Ni), lead (Pb), titanium (Ti), and/or any alloy thereof, but example embodiments are not limited thereto.

According to some example embodiments, the second insulation pattern 140 may surround or at least partially surround the wiring pattern 130. For example, when viewed in the first direction D1 which is perpendicular to the metal plate 110, the second insulation pattern 140 may have a ring shape surrounding or at least partially surrounding the wiring pattern 130 having the circular shape. The wiring pattern 130 may be disposed in the ring shape of the second insulation pattern 140. An inner side surface of the second insulation pattern 140 may surround or at least partially surround a side surface of the wiring pattern 130.

FIG. 1 illustrates that when viewed in the first direction D1, the wiring pattern 130 has the circular shape and the second insulation pattern 140 has a circular ring shape, but example embodiments are not limited thereto. For example, when viewed in the first direction D1, the wiring pattern 130 may have a quadrangular shape and the second insulation pattern 140 may have a quadrangular ring shape.

According to some example embodiments, the second insulation pattern 140 may electrically insulate the wiring pattern 130 from the metal plate 110. The second insulation pattern 140 may include the insulation material. For example, the second insulation pattern 140 may include the oxide film, the nitride film, the carbide film, the polymer, or the combination thereof, but example embodiments are not limited thereto. According to some example embodiments, the second insulation pattern 140 may include the photoimageable dielectric (PID) or the photosensitive polyimide (PSPI). The second insulation pattern 140 may include a material identical to that of the first insulation pattern 120, but example embodiments are not limited thereto. The second insulation pattern 140 and the first insulation pattern 120 may be formed in an identical process, but example embodiments are not limited thereto.

According to some example embodiments, an outer side surface 120SW of the first insulation pattern may be exposed from the side surface 110SW of the metal plate. Specifically, the outer side surface 120SW of the first insulation pattern and the side surface 110SW of the metal plate may be disposed on an identical plane. The outer side surface 120SW of the first insulation pattern may not be covered by the side surface 110SW of the metal plate and exposed from the side surface 110SW of the metal plate.

According to some example embodiments, the outer side surface 120SW of the first insulation pattern may be an outer side surface of the first penetration part 121. The outer side surface of the first penetration part 121 and the side surface 110SW of the metal plate may be disposed on an identical plane (for example, be coplanar with each other). In the third direction D3, a width W_120SW of the outer side surface of the first insulation pattern may be larger than the width W124 of the connection part. That is, in the third direction D3, a width of the outer side surface of the first penetration part 121 may be larger than the width W124 of the connection part.

According to some example embodiments, a first side surface 101SW1 of the wiring layer may include the side surface 110SW of the metal plate and the side surface 120SW of the first insulation pattern. That is, all of the metal plate 110 and the first insulation pattern 120 may be exposed at the first side surface 101SW1 of the wiring layer. The side surface 120SW of the first insulation pattern and the side surface 110SW of the metal plate which are disposed on the identical plane may form the first side surface 101SW1 of the wiring layer.

According to some example embodiments, a second side surface 101SW2 of the wiring layer may be a surface different from the first side surface 101SW1 of the wiring layer. As an example, a side surface crossing the first side surface 101SW1 of the wiring layer may be referred to as the second side surface 101SW2 of the wiring layer. As another example, a side surface disposed opposite to the first side surface 101SW1 of the wiring layer may be referred to as the second side surface 101SW2 of the wiring layer.

According to some example embodiments, the second side surface 101SW2 of the wiring layer may include only a surface of the metal plate 110 except for the first insulation pattern 120. Specifically, since the first insulation pattern 120 is not exposed through the second side surface 101SW2 of the wiring layer, only a side surface of the metal plate 110 may form the second side surface 101SW2 of the wiring layer.

According to some example embodiments, the via layer 102 may overlap or at least partially overlap with the wiring layer 101 in the first direction D1. The via layer 102 may be disposed below the wiring layer 101. However, example embodiments are not limited thereto. For example, the via layer 102 may be disposed above the wiring layer 101 unlike illustrations in FIGS. 2, 3, and 5. In other words, in the redistribution structure 100 which is one unit including the wiring layer 101 and the via layer 102 stacked on each other, the wiring layer 101 may be disposed above the via layer 102, and the wiring layer 101 may be disposed below the via layer 102 as well.

According to some example embodiments, the via layer 102 may include the via pattern 150 and the insulation film 160.

According to some example embodiments, the via pattern 150 may penetrate (for example, extend or at least partially extend through) the insulation film 160 in the first direction D1. The via pattern 150 may be disposed in the insulation film 160. For example, a side surface of the via pattern 150 may be surrounded or at least partially surrounded by the insulation film 160. The via pattern 150 may overlap or at least partially overlap with the wiring pattern 130 in the first direction D1. The via pattern 150 may be electrically connected with the wiring pattern 130. The via pattern 150 may include copper (Cu), aluminum (Al), silver (Ag), tin (Sn), gold (Au), nickel (Ni), lead (Pb), titanium (Ti), and/or any alloy thereof, but example embodiments are not limited thereto.

According to some example embodiments, the insulation film 160 may be disposed on a lower surface of the wiring layer 101 in the first direction D1. The insulation film 160 may cover or at least partially cover the lower surface of the wiring layer 101. For example, the insulation film 160 may cover or at least partially cover the lower surface of the first insulation pattern 120. The insulation film 160 may surround or at least partially surround the via pattern 150. The insulation film 160 may electrically insulate a plurality of via patterns 150.

According to some example embodiments, the insulation film 160 may overlap or at least partially overlap with the first insulation pattern 120 and the metal plate 110 in the first direction D1. For example, when a plurality of redistribution structures 100 is stacked in the first direction D1, the insulation film 160 may be disposed between adjacent metal plates 110 in the first direction D1 to electrically insulate the metal plates 110.

According to some example embodiments, the insulation film 160 may include an oxide film, a nitride film, a carbide film, a polymer, or a combination thereof, but example embodiments are not limited thereto. According to some example embodiments, the insulation film 160 may include, for example, photoimageable dielectric (PID) and/or photosensitive polyimide (PSPI).

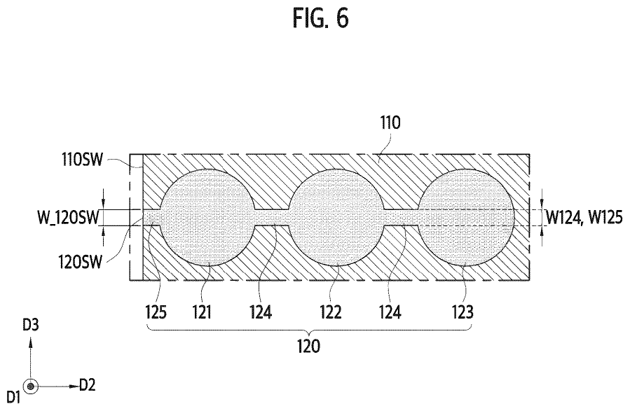

FIGS. 6 through 10 are diagrams illustrating a redistribution structure according to some other example embodiments. For convenience of description, the following description will mainly focus on a point different from that described above with reference to FIGS. 1 through 5.

According to some example embodiments, a shape of the first insulation pattern 120 may be variously changed depending on example embodiments.

Referring to FIG. 6, the first insulation pattern 120 may further include an extension part 125. The extension part 125 may penetrate (for example, extend or at least partially extend through) the metal plate 110 in the first direction D1. The extension part 125 may be extended (for example, may extend) from the first penetration part 121 toward the side surface 110SW of the metal plate. The extension part 125 may be extended from the first penetration part 121 to the side surface 110SW of the metal plate.

According to some example embodiments, the extension part 125 and the connection part 124 may be extended (for example, may extend) in an identical (for the example, a same) direction. For example, the extension part 125 and the connection part 124 may be extended in the second direction D2. A width W125 of the extension part may be equal to the width W124 of the connection part in the third direction D3 which crosses the second direction D2.

According to some example embodiments, the outer side surface 120SW of the first insulation pattern may be an outer side surface of the extension part 125. In other words, the side surface 120SW of the first insulation pattern may be a side surface of the extension part 125, which is exposed from the side surface 110SW of the metal plate. At this point, the side surface of the extension part 125 and the side surface 110SW of the metal plate may be disposed on an identical plane. In the third direction D3, the width W_120SW of the outer side surface of the first insulation pattern may be equal to the width W124 of the connection part. For example, in the third direction D3, since the width W_120SW of the outer side surface of the first insulation pattern is the width W125 of the extension part, the width W_120SW of the outer side surface of the first insulation pattern may be equal to the width W124 of the connection part.

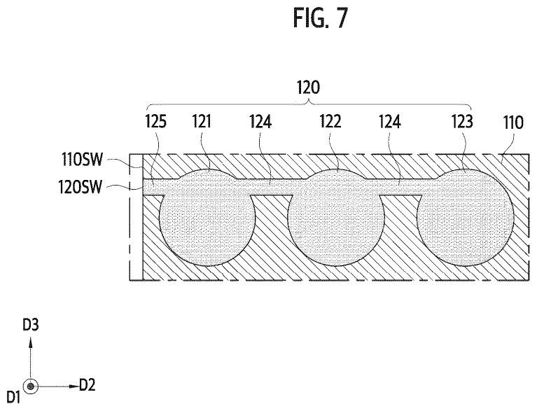

Referring to FIG. 7, the connection part 124 and the extension part 125 may not be connected with center portions of the penetration parts 121, 122, and 123. For example, the connection part 124 and the extension part 125 may not be aligned with the center portions of the penetration parts 121, 122, and 123 which have a circular shape. In the third direction D3, each of the penetration parts 121, 122, and 123 may be disposed in an asymmetrical structure around the connection part 124 and the extension part 125. In the third direction D3, the connection part 124 and the extension part 125 may be disposed closer to a side from a center portion of each of the penetration parts 121, 122, and 123.

According to some example embodiments, an imaginary line connecting the connection part 124 and the extension part 125 may not pass through centers of the penetration parts 121, 122, and 123 having the circular shape. In addition, the imaginary line connecting the connection part 124 and the extension part 125 may cut the penetration parts 121, 122, and 123 having the circular shape in an asymmetrical structure in the second direction D2. For example, the imaginary line connecting the connection part 124 and the extension part 125 may cut the penetration parts 121, 122, and 123 individually in circular segments different in size.

In such a case, the side surface 120SW of the first insulation pattern which includes the side surface of the extension part 125 may be exposed from the side surface 110SW of the metal plate to be disposed on an identical plane together with the side surface 110SW of the metal plate.

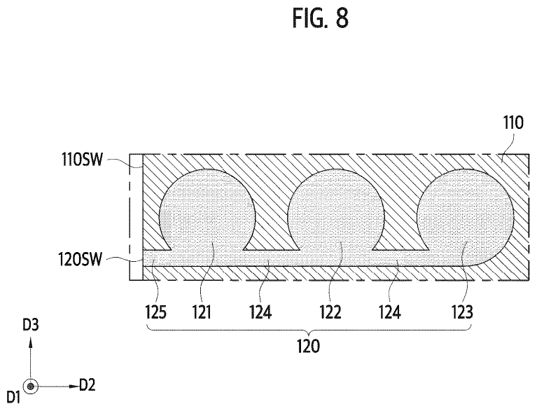

Referring to FIG. 8, the connection part 124 may be directly connected with outer circumferences of the penetration parts 121, 122, and 123. Specifically, the imaginary line connecting the connection part 124 and the extension part 125 may not pass through the centers of the penetration parts 121, 122, and 123 having the circular shape. Also, the imaginary line connecting the connection part 124 and the extension part 125 may not cut each of the penetration parts 121, 122, and 123. The connection part 124 and the extension part 125 may be extended in the first direction D1 and connected to be in contact with the respective outer circumferences of the penetration parts 121, 122, and 123 in the second direction D2.

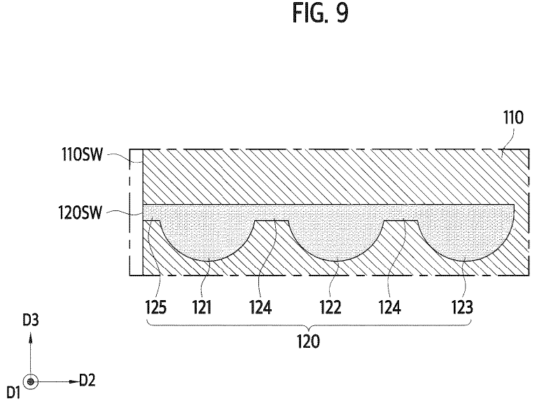

Referring to FIG. 9, the penetration parts 121, 122, and 123 may have a semicircular shape when viewed in the first direction D1, not the circular shape. The connection part 124 and the extension part 125 may be disposed on an identical imaginary line in the second direction D2, and the penetration parts 121, 122, and 123 which have the semicircular shape may be individually disposed at an identical side in the third direction D3 around the connection part 124 and the extension part 125.

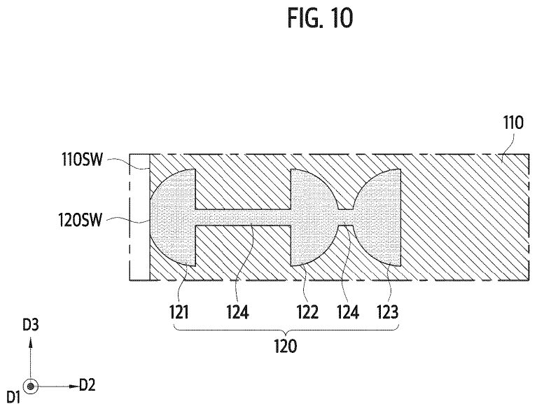

Referring to FIG. 10, the penetration parts 121, 122, and 123 may have the semicircular shape when viewed in the first direction D1. For example, the first penetration part 121 and the second penetration part 122 may be symmetrically disposed around the connection part 124 in the first direction D1. The second penetration part 122 and the third penetration part 123 may be symmetrically disposed in the first direction D1 around the connection part 124 which is disposed in between.

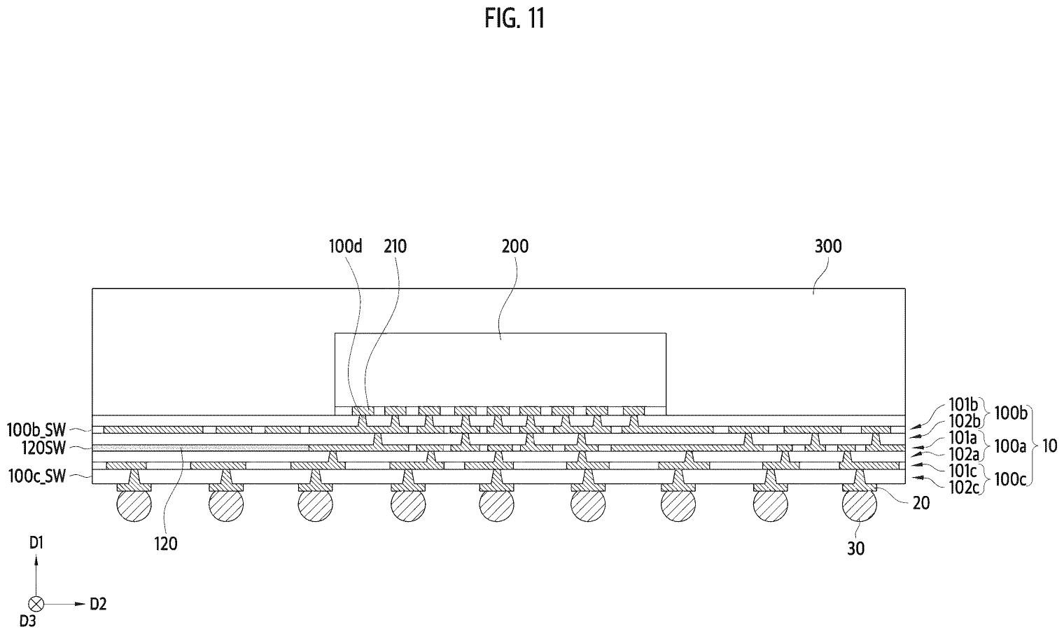

FIG. 11 is a diagram illustrating semiconductor package according to some example embodiments.

Referring to FIG. 11, the semiconductor package according to some example embodiments may include a package substrate 10, a semiconductor chip 200, and a mold film 300.

According to some example embodiments, the package substrate 10 may be disposed below the semiconductor chip 200. The package substrate 10 may be electrically connected with the semiconductor chip 200. The semiconductor chip 200 may send and receive an electrical signal to and from an external device through the package substrate 10. For example, the package substrate 10 may be a printed circuit board (PCB), a ceramic wiring substrate, or the like, but example embodiments are not limited thereto.

In some example embodiments, an external connection terminal 30 may be disposed on a lower surface of the package substrate 10. The external connection terminal 30 may be attached to an external connection pad 20. The external connection terminal 30 may be a solder ball or a solder bump. The external connection terminal 30 may have, for example, a spherical shape or an oval spherical shape, but example embodiments are not limited thereto.

According to some example embodiments, the external connection terminal 30 may electrically connect the package substrate 10 with the external device. Accordingly, the external connection terminal 30 may provide an electrical signal to the package substrate 10 or provide, to the external device, an electrical signal provided from the package substrate 10.

In some example embodiments, the external connection terminal 30 may include, for example, at least one of tin (Sn), indium (In), lead (Pb), zinc (Zn), nickel (Ni), gold (Au), copper (Cu), antimony (Sb), bismuth (Bi), and a combination thereof, but example embodiments are not limited thereto.

According to some example embodiments, the package substrate 10 may include a first redistribution structure 100a, a second redistribution structure 100b, and a third redistribution structure 100c. The first redistribution structure 100a may correspond to the redistribution structure 100 described with reference to FIGS. 1 through 10. Hereinafter, the first redistribution structure 100a will be described.

According to some example embodiments, the first redistribution structure 100a, the second redistribution structure 100b, and the third redistribution structure 100c may be stacked in the first direction D1. The first redistribution structure 100a may be disposed between the second redistribution structure 100b and the third redistribution structure 100c. For example, the first redistribution structure 100a may be disposed below the second redistribution structure 100b. The first redistribution structure 100a may be disposed on the third redistribution structure 100c.

According to some example embodiments, the first redistribution structure 100a may include a first wiring layer 101a and a first via layer 102a. Since the first wiring layer 101a corresponds to the wiring layer 101 described with reference to FIGS. 1 through 10, and since a first via layer 102a, redundant descriptions will be omitted.

According to some example embodiments, the second redistribution structure 100b may include a second wiring layer 101b and a second via layer 102b. The third redistribution structure 100c may include a third wiring layer 101c and a third via layer 102c. The second wiring layer 101b and the second via layer 102b may correspond to the wiring layer 101 and the via layer 102, respectively, which are described with reference to FIGS. 1 through 10. In addition, the third wiring layer 101c and the third via layer 102c may correspond to the wiring layer 101 and the via layer 102, respectively, which are described with reference to FIGS. 1 through 10.

According to some example embodiments, the package substrate 10 may include a wiring line. Wiring lines of the package substrate 10 may include the metal plate 110 (of FIG. 5) and the wiring pattern 130 (of FIG. 5) of respective wiring layers 101a, 101b, and 101c of the first redistribution structure 100a, the second redistribution structure 100b, and the third redistribution structure 100c and include the via pattern 150 (of FIG. 5) of respective via layers 102a, 102b, and 102c of the first redistribution structure 100a, the second redistribution structure 100b, and the third redistribution structure 100c. The wiring line of the package substrate 10 may include copper (Cu), aluminum (Al), silver (Ag), tin (Sn), gold (Au), nickel (Ni), lead (Pb), titanium (Ti), and/or any alloy thereof, but example embodiments are not limited thereto.

According to some example embodiments, the first redistribution structure 100a may include the first insulation pattern 120. As being identical to the above description of the first insulation pattern 120 described with reference to FIGS. 1 through 10, a description of the first insulation pattern 120 in the package substrate 10 will be omitted.

According to some example embodiments, the first insulation pattern 120 may be disposed between the insulation film 160 (of FIG. 5) of the first via layer 102a and an insulation film of the second via layer 102b. The first insulation pattern 120 may overlap or at least partially overlap with the insulation film 160 (of FIG. 5) of the first via layer 102a and the insulation film of the second via layer 102b in the first direction D1.

According to some example embodiments, the first insulation pattern 120 may overlap or at least partially overlap with a metal plate of the second wiring layer 101b and a metal plate of the third wiring layer 101c in the first direction D1. For example, when the first insulation pattern 120 is not disposed to the first redistribution structure 100a, the metal plate 110 (of FIG. 5) of the first wiring layer 101a may be disposed at a portion at which the first insulation pattern 120 is disposed, so that the metal plate 110 (of FIG. 5) of the first wiring layer 101a, the metal plate of the second wiring layer 101b, and the metal plate of the third wiring layer 101c may be overlapped in the first direction D1. In such a case, parasitic capacitance may be occur between the metal plate 110 (of FIG. 5) of the first wiring layer 101a, the metal plate of the second wiring layer 101b, and the metal plate of the third wiring layer 101c. When parasitic capacitance occurs, electrical reliability of the semiconductor package may be decreased because an intervention in electrical signal transmission occurs.

Accordingly, overlapping of the metal plate 110 (of FIG. 5) of the first wiring layer 101a, the metal plate of the second wiring layer 101b, and the metal plate of the metal plate of the third wiring layer 101c in the first direction D1 may be minimized by disposing the first insulation pattern 120, and parasitic capacitance may be reduced or prevented.

According to some example embodiments, the side surface 120SW of the first insulation pattern, a side surface 100b_SW of the second redistribution structure, and a side surface 100c_SW of the third redistribution structure may be disposed on an identical plane (for example, be coplanar with each other). At this point, an outer side surface of the first insulation pattern 120 may be referenced to as the side surface 120SW of the first insulation pattern.

According to some example embodiments, the semiconductor chip 200 may be disposed on the package substrate 10. The semiconductor chip 200 may be electrically connected with the package substrate 10 through a connection pad 210. FIG. 11 illustrates that the connection pad 210 of the semiconductor chip 200 is directly connected with a connection via 100d of the package substrate 10, but example embodiments are not limited thereto. As an example, the semiconductor chip 200 may be bonded on the package substrate 10 in a flip chip bonding manner. As another example, the semiconductor chip 200 may be bonded on the package substrate 10 in a wire bonding manner.

According to some example embodiments, the semiconductor chip 200 may be or include an integrated circuit (IC) in which hundreds to millions or more of semiconductor devices are each integrated in one chip. For example, the semiconductor chip 200 may include an application processor chip such as a microprocessor or a microcontroller, a central processing unit (CPU), a graphic processing unit (GPU), a modem, a logic chip such as an application-specific IC (ASIC) and a field programmable gate array (FPGA), or a volatile memory chip such as a dynamic random access memory (DRAM) and a static random access memory (SRAM), a non-volatile memory chip such as a phase-change random access memory (PRAM), a magnetoresistive random access memory (MRAM), and a ferroelectric random access memory (FeRAM), a flash memory, a high bandwidth memory (HBM), a combination thereof, and/or the like, but example embodiments are not limited thereto.

According to some example embodiments, the mold film 300 may cover or at least partially cover the semiconductor chip 300 on the package substrate 10. The mold film 300 may surround or at least partially surround the semiconductor chip 200. Specifically, the mold film 300 may surround or at least partially surround a side surface of the semiconductor chip 200. The semiconductor chip 200 may be disposed in the mold film 300.

For example, the mold film 300 may include an insulating polymer material such as an epoxy molding compound (EMC), but example embodiments are not limited thereto. The mold film 300 may include, for example, a thermosetting resin such an epoxy resin, a thermoplastic resin such as polyimide, or a resin including a reinforcing material such as a filler in addition to the thermosetting resin or the thermoplastic resin, such as Ajinomoto Build-up Film (ABF), FR-4, or a bismaleimide triazine (BT) resin.

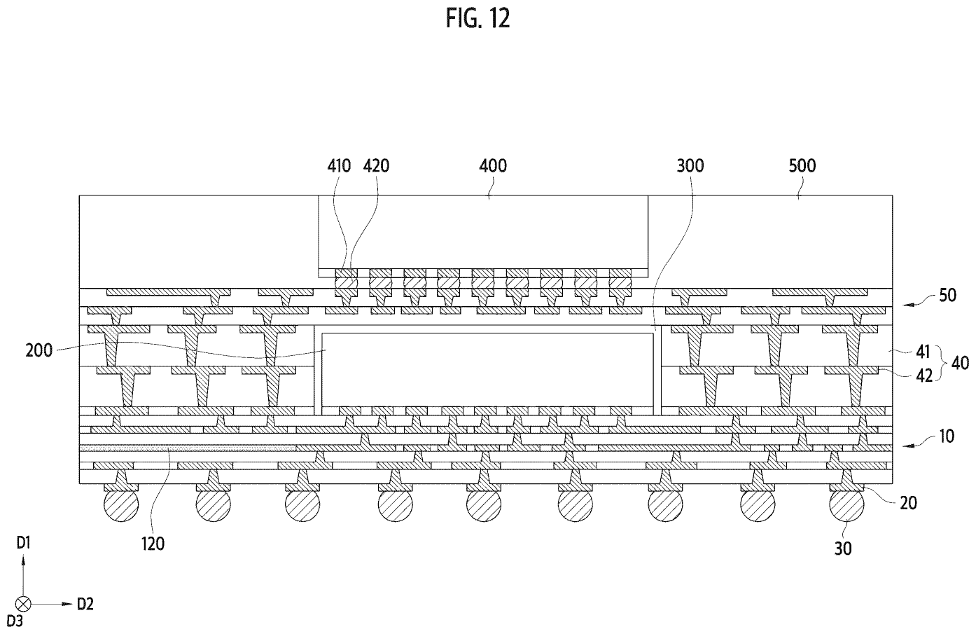

FIG. 12 is a diagram illustrating a semiconductor package according to some other example embodiments. For convenience of description, the following description will mainly focus on a point different from that described above with reference to FIG. 11.

Referring to FIG. 12, the semiconductor package according to some other example embodiments may have a package-on-package (POP) structure. For example, the semiconductor package may include a lower package to which a first semiconductor chip 200 is disposed and an upper package disposed on the lower package and including a second semiconductor chip 400. The first semiconductor chip 200 may correspond to the semiconductor chip 200 which is described with reference to FIG. 11.

According to some example embodiments, the semiconductor package may include a lower package substrate 10 and an upper package substrate 50. The lower package substrate 10 may correspond to the package substrate 10 described with reference to FIG. 11.

According to some example embodiments, a connection wiring structure 40 surrounding or at least partially surrounding the first semiconductor chip 200 may be disposed on the lower package substrate 10. The connection wiring structure 40 may electrically connect the upper package substrate 50 and the lower package substrate 10. The connection wiring structure 40 may include a connection insulation film 41 and a connection wiring line 42.

According to some example embodiments, the connection insulation film 41 may include, for example, a photoimageable dielectric. As an example, the connection insulation film 41 may include a photosensitive polymer. The photosensitive polymer may be formed of, for example, at least one of photosensitive polyimide, polybenzoxazole, a phenolic polymer, or a benzocyclobutene-based polymer, but example embodiments are not limited thereto. As another example, the connection insulation film 41 may be formed of a silicon oxide film, a silicon nitride film, or a silicon oxynitride film.

According to some example embodiments, the connection wiring line 42 may be disposed in the connection insulation film 41. The connection wiring line 42 may include a wiring pattern extended in parallel with the lower package substrate 10 and a wiring via extended to be perpendicular to the lower package substrate 10. The connection wiring line 42 may have a multilayer structure in which two or more wiring patterns or two or more wiring vias are stacked alternately. The connection wiring line 42 may include a conductive material. For example, the wiring pattern 42 may include copper (Cu), aluminum (Al), silver (Ag), tin (Sn), gold (Au), nickel (Ni), lead (Pb), titanium (Ti), and/or any alloy thereof, but example embodiments are not limited thereto.

According to some example embodiments, the upper package substrate 50 may be disposed on the semiconductor chip 200. A description of the upper package substrate 50 may be identical to a description of the lower package substrate 10. The second semiconductor chip 400 may be disposed on the upper package substrate 50. For example, the second semiconductor chip 400 may be bonded on the upper package substrate 50 in a flip chip bonding manner. The second semiconductor chip 400 may be surrounded or at least partially surrounded by a second mold film 500 on the upper package substrate 50.

According to some example embodiments, the second semiconductor chip 400 may include a connection pad 410 and a connection bump 420 in a lower part. The semiconductor chip 400 may be electrically connected with the upper package substrate 50 through the connection pad 410 and the connection bump 420. The connection pad 410 and the connection bump 420 may include the conductive material. For example, the connection pad 410 and the connection bump 420 may include copper (Cu), aluminum (Al), silver (Ag), tin (Sn), gold (Au), nickel (Ni), lead (Pb), titanium (Ti), and/or any alloy thereof, but example embodiments are not limited thereto.

FIG. 12 illustrates that the first insulation pattern 120 is disposed only to the lower package substrate 10, but example embodiments are not limited thereto. For example, the first insulation pattern 120 may be disposed to the upper package substrate 50.

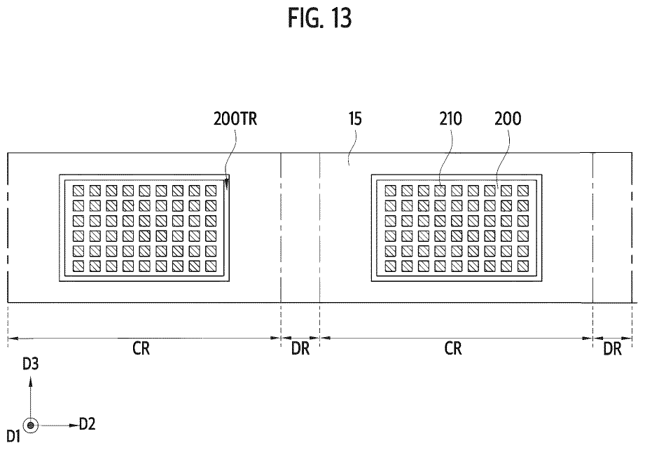

FIGS. 13 through 20 are diagrams illustrating an intermediate operation for a method of manufacturing a semiconductor package according to some example embodiments. For reference, FIGS. 13 through 20 illustrate the intermediate operation in the method of manufacturing the semiconductor package which includes the first insulation pattern 120 having a shape illustrated in FIG. 6. In addition, for reference, FIGS. 13 through 20 illustrate the intermediate operation in the method of manufacturing the semiconductor package which is illustrated in FIG. 11.

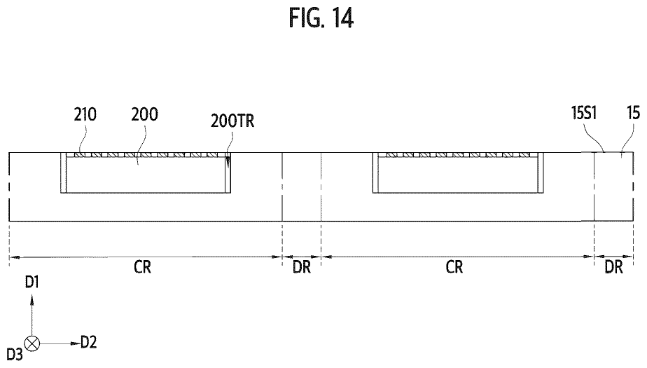

Referring to FIGS. 13 and 14, the semiconductor chip 200 may be disposed on a carrier substrate 15. The carrier substrate 15 may be used to temporarily support the semiconductor chip 200 in a process of manufacturing the semiconductor package. For example, the carrier substrate 15 may be an insulation substrate including glass or a polymer, but example embodiments are not limited thereto.

According to some example embodiments, the carrier substrate 15 may include a chip region CR and a dummy region DR. The chip region CR may a region in which the semiconductor chip 200 is disposed. The dummy region DR may be disposed between chip regions CR. The dummy region DR may be a region that is cut in order to separate each chip region CR after the semiconductor package is manufactured.

According to some example embodiments, a chip trench 200TR to mount the semiconductor chip 200 to may be disposed to the carrier substrate 15. The semiconductor chip 200 may be inserted into the chip trench 200TR.

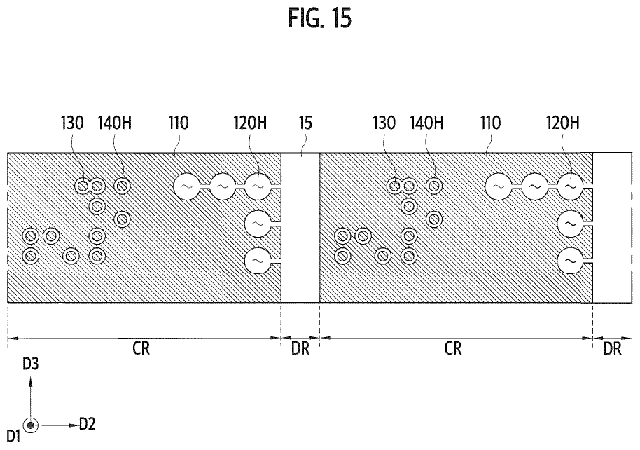

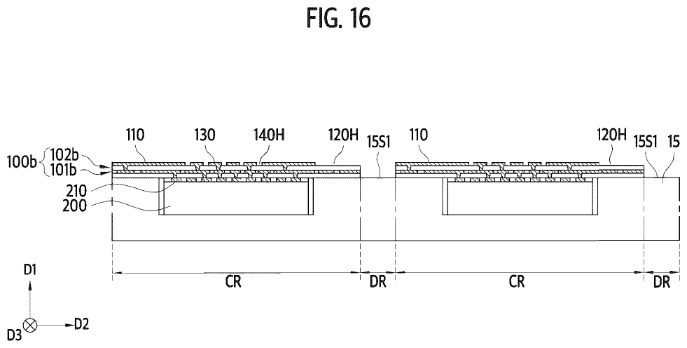

Then, referring to FIGS. 15 and 16, the second redistribution structure 100b may be formed on the semiconductor chip 200, and the metal plate 110 and the wiring pattern 130 may be formed on the second redistribution structure 100b. The wiring pattern 130 may be connected with a via pattern of the second via layer 102b of the second redistribution structure 100b.

According to some example embodiments, the metal plate 110 may be patterned, such that a first insulation pattern hole 120H and a second insulation pattern hole 140H may penetrate (for example, extend or at least partially extend through) the metal plate 110. The first insulation pattern hole 120H may have, for example, shapes individually corresponding to the penetration parts 121, 122, and 123 (of FIG. 4), the connection part 124 (of FIG. 4), and the extension part 125 (of FIG. 4).

According to some example embodiments, the second redistribution structure 100b may be formed in the chip region CR and may not be formed in the dummy region DR. The second redistribution structure 100b may overlap or at least partially overlap with the chip region CR of the carrier substrate 15 in the first direction D1. The second redistribution structure 100b may not overlap the dummy region DR of the carrier substrate 15 in the first direction D1. For example, a first surface 15S1 of the carrier substrate in the dummy region DR may be exposed between second redistribution structures 100b on the chip regions CR.

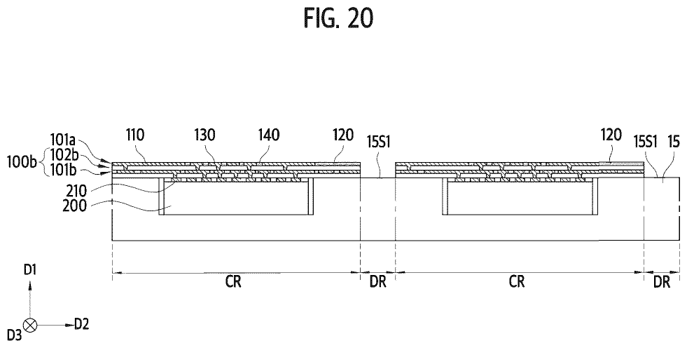

According to some example embodiments, the first insulation pattern hole 120H may be formed in the chip region CR. The first insulation pattern hole 120H may be connected with the dummy region DR. The first insulation pattern hole 120H may be formed at a portion overlapping (for example, at least partially overlapping with) a metal plate of the second wiring layer 101b in the first direction D1. For example, an area in which the metal plate 110 of the first wiring layer 101a (of FIG. 20) and the metal plate of the second wiring layer 101b are overlapped in the first direction D1 may be reduced through the first insulation pattern hole 120H. Accordingly, parasitic capacitance occurring between the metal plate 110 of the first wiring layer 101a (of FIG. 20) and the metal plate of the second wiring layer 101b may be decreased.

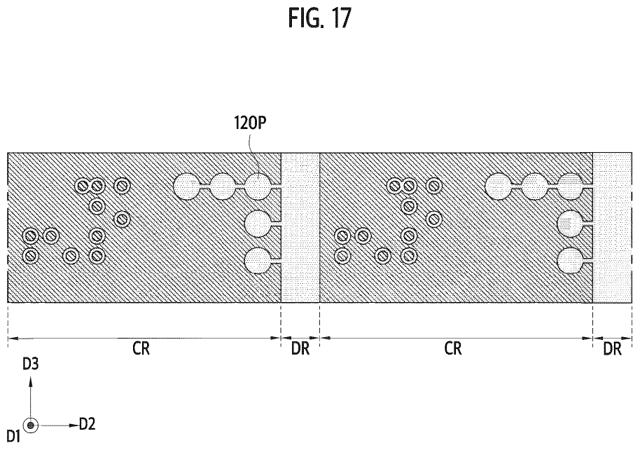

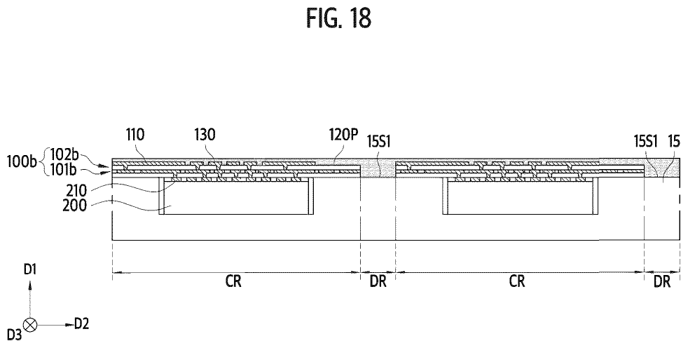

Then, referring to FIGS. 17 and 18, a pre-insulation pattern 120P may be formed on the metal plate 110 and the wiring pattern 130. The pre-insulation pattern 120P may fill or at least partially fill the first insulation pattern hole 120H (of FIGS. 15 and 16) and the second insulation pattern hole 140H (of FIGS. 15 and 16). The pre-insulation pattern 120P may cover or at least partially cover the first surface 15S1 of the carrier substrate in the dummy region DR.

According to some example embodiments, as the first insulation pattern hole 120H (of FIGS. 15 and 16) has a step from the metal plate 110, an air gap may be formed in a process of forming the pre-insulation pattern 120P. When the air gap is formed in the pre-insulation pattern 120 P in the chip region CR, a defect may be caused by expansion of the air gap in a subsequent process or the like. Meanwhile, since the first insulation pattern hole 120H (of FIGS. 15 and 16) is connected with the dummy region DR, the air gap may be vented into the dummy region DR even if the air gap is formed in the process of forming the pre-insulation pattern 120P. Accordingly, although the air gap is formed due to the step between the first insulation pattern hole 120H (of FIGS. 15 and 16) and the metal plate 110, when the pre-insulation pattern 120P is formed, the air gap may be vented into the dummy region DR not to remain in the chip region CR.

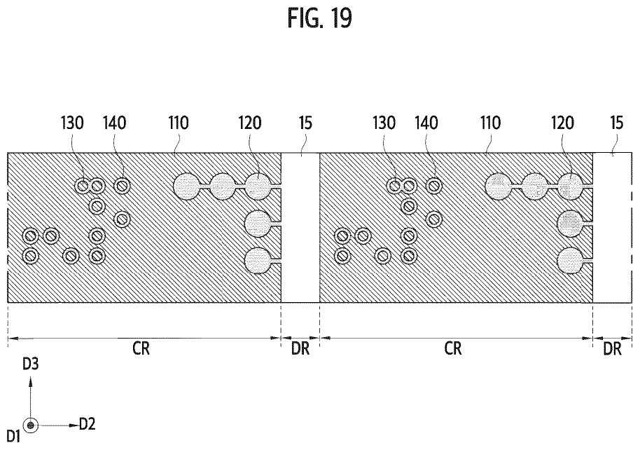

Then, referring to FIGS. 19 and 20, the pre-insulation pattern 120P (of FIGS. 17 and 18) which covers or at least partially covers the metal plate 110 and the wiring layer 130 may be removed, so that the first wiring layer 101a which includes the first insulation pattern 120 and the second insulation pattern 140 may be formed. In addition, the pre-insulation pattern 120P (of FIGS. 17 and 18) may be removed in the dummy region DR, so that the first surface 15S1 of the carrier substrate may be exposed.

Then, referring to FIG. 11, the first via layer 102a, the third redistribution structure 100c, the external connection pad 20, and the external connection terminal 30 may be formed on the first wiring layer 101a. After the package substrate 10 is formed, the chip region CR (of FIGS. 19 and 20) may be separated by cutting the dummy region DR (of FIGS. 29 and 20). As the dummy region DR (of FIGS. 19 and 20) is removed, the air gap may not be disposed in the first insulation pattern 120 in the chip region CR (of FIGS. 19 and 20).

According to some example embodiments, the first insulation pattern 120 and the metal plate 110 may be exposed together at a side surface of the chip region CR (of FIGS. 19 and 20), which is exposed because the dummy region DR (of FIGS. 19 and 20) is cut. In other words, all of the first insulation pattern 120 and the metal plate 110 may be disposed to a bonding surface of the dummy region DR (of FIGS. 19 and 20) and the chip region CR (of FIGS. 19 and 20). This may be caused by connection, to the dummy region DR (of FIGS. 15 and 16), of the first insulation pattern hole 120H (of FIGS. 15 and 16) to which the first insulation pattern 120 penetrating the metal plate 110 in the chip region CR (of FIGS. 19 and 20) is formed.

Various example embodiments of the present disclosure have been described above in detail, but the spirit and scope of inventive are not limited thereto. It will be apparent to those ordinarily skilled in the art that various changes and modifications may be allowed within the spirit scope of the technical spirit of inventive concepts. In addition, the above-described example embodiments may be implemented without a portion of elements thereof, and each of the example embodiments may be implemented in combination with another.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A redistribution structure, comprising:
a via layer; and
a wiring layer on the via layer in a first direction perpendicular to the via layer,
wherein the wiring layer comprises a metal plate and a first insulation pattern, the first insulation pattern penetrating the metal plate in the first direction, and
wherein an outer side surface of the first insulation pattern is exposed from a side surface of the metal plate.

2. The redistribution structure of claim 1, wherein the first insulation pattern comprises:
a first penetration part and a second penetration part that penetrate the metal plate in the first direction; and
a connection part connecting the first penetration part to the second penetration part.

3. The redistribution structure of claim 2, wherein
the via layer comprises a via pattern;
the wiring layer further comprises a wiring pattern and a second insulation pattern, the wiring pattern connected to the via pattern, the second insulation pattern at least partially surrounding the wiring pattern, and
a maximum width of the first penetration part is larger than a maximum width of the second insulation pattern.

4. The redistribution structure of claim 2, wherein
the connection part extends in a second direction, the second direction crossing the first direction and parallel to a surface of the metal plate, and
a width of the connection part is smaller than a width of the first penetration part and a width of the second penetration part in a third direction, the third direction being parallel to the surface of the metal plate and crossing the first direction and the second direction.

5. The redistribution structure of claim 2, wherein each of the first penetration part and the second penetration part has a circular shape when viewed in the first direction.

6. The redistribution structure of claim 2, wherein the first insulation pattern further comprises:
an extension part extending from the first penetration part to the side surface of the metal plate.

7. The redistribution structure of claim 6, wherein
the connection part and the extension part extend in a second direction, the second direction being parallel to a surface of the metal plate and crossing the first direction, and
a width of the connection part and a width of the extension part are equal in a third direction, the third direction being parallel to the surface of the metal plate and crossing the first direction and the second direction.

8. The redistribution structure of claim 2, wherein a side surface of the first penetration part and the side surface of the metal plate are coplanar with each other.

9. The redistribution structure of claim 8, wherein
the connection part extends in a second direction that is parallel to a surface of the metal plate and crosses the first direction, and
a width of an outer side surface of the first penetration part is larger than a width of the connection part in a third direction, the third direction being parallel to the surface of the metal plate and crossing the first direction and the second direction.

10. The redistribution structure of claim 1, wherein
the via layer comprises a via pattern and an insulation film that is penetrated by the via pattern in the first direction, and
a lower surface of the first insulation pattern is in contact with an upper surface of the insulation film.

11. The redistribution structure of claim 10, wherein the first insulation pattern comprises a photoimageable dielectric material.

12. A semiconductor package, comprising:
a package substrate comprising a first redistribution structure; and
a semiconductor chip on the package substrate and electrically connected to the first redistribution structure,
wherein the first redistribution structure comprises a first via layer and a first wiring layer on the first via layer in a first direction, the first direction being perpendicular to the first via layer, the first wiring layer comprising a metal plate and a first insulation pattern, the first insulation pattern penetrating the metal plate in the first direction, and
wherein an outer side surface of the first insulation pattern and a side surface of the metal plate are coplanar with each other.

13. The semiconductor package of claim 12, wherein the first insulation pattern comprises:
a first penetration part and a second penetration part that penetrate the metal plate; and
a connection part that connects the first penetration part to the second penetration part.

14. The semiconductor package of claim 13, wherein a thickness of the first penetration part, a thickness of the second penetration part, and a thickness of the connection part are equal in the first direction.

15. The semiconductor package of claim 13, wherein
the connection part extends in a second direction, the second direction being parallel to the metal plate and crossing the first direction, and
a width of the connection part is smaller than a width of the first penetration part and a width of the second penetration part in a third direction, the third direction being parallel to the metal plate and crossing the first direction and the second direction.

16. The semiconductor package of claim 15, wherein a width of the outer side surface of the first insulation pattern is greater than or equal to the width of the connection part in the third direction.

17. The semiconductor package of claim 12, wherein the package substrate further comprises:
a second redistribution structure on the first wiring layer in the first direction; and
a third redistribution structure below the first via layer in the first direction,
the second redistribution structure comprises a second via layer on the first wiring layer, and
the first insulation pattern is between an insulation film of the first via layer and an insulation film of the second via layer.

18. The semiconductor package of claim 17, wherein the outer side surface of the first insulation pattern, a side surface of the second redistribution structure, and a side surface of the third redistribution structure are coplanar with each other.

19. The semiconductor package of claim 12, further comprising:
a molding film at least partially surrounding the semiconductor chip on the package substrate.

20. A redistribution structure, comprising:
a via layer comprising an insulation film and a via pattern penetrating the insulation film; and
a wiring layer comprising a metal plate and a first insulation pattern, the metal plate being on the via layer, the first insulation pattern penetrating the metal plate, wherein
the first insulation pattern comprises a first penetration part, a second penetration part, and a connection part, the first penetration part and the second penetration part penetrating the metal plate, the connection part connecting the first penetration part to the second penetration part,
a first side surface of the wiring layer comprises an outer side surface of the first insulation pattern and a first side surface of the metal plate that are coplanar with each other, and
a second side surface of the wiring layer comprises only the metal plate except for the first insulation pattern.
